(19) United States
(12) Patent Application Publication
(10) Pub. No.: US 2026/0300588 A1
(43) Pub. Date: Oct. 1, 2026

(54) METHODS AND DEVICES FOR GENERATING A DIGITAL PLUG FROM DRILL CUTTINGS

(71) Applicant: UNIVERSITY OF WYOMING, Laramie, WY (US)

(72) Inventors: Bradley MCCASKILL, Laramie, WY (US); Mohammad PIRI, Laramie, WY (US)

(21) Appl. No.: 19/479,264

(22) PCT Filed: Apr. 26, 2024
(86) PCT No.: PCT/US2024/026432

§ 371 Date: Oct. 27, 2025

Related U.S. Application Data
(60) Provisional application No. 63/462,629, filed on Apr. 28, 2023.

(51) Int. Cl. G06F 30/28

(52) U.S. Cl. CPC G06F 30/28

(57) ABSTRACT

A method and system for pore network extraction are disclosed. The method for pore network generation by one or more central processing units (CPU) includes obtaining a representative pore network having a set of representative pore elements corresponding to a porous media sample. The selection of seed elements are randomized for the representative pore network. The seed elements are inflated to define a set of volumes and a set of buffer zones. The representative pore network is duplicated to produce a set of generated pore networks. The set of generated pore networks are stitched according to the set of volumes and set of buffer zones to produce a digital plug.

### BACKGROUND

### Field

Aspects of the present disclosure generally relate to the characterization of porous media, and more particularly, to generating a digital plug from drill cuttings.

### Description of the Related Art

Modeling techniques for fluid flow through porous media are broadly implemented for petroleum resource development, materials engineering, food packaging, and medical technology development. Fluid flow modeling techniques may be equipped to illustrate both physical and chemical media properties like permeability, capillary pressure, fluid saturation, contact angle, wettability, or other similar properties, which may be used to characterize fluid behavior.

Although current techniques for modelling fluid flow through porous media are based on technological advancements made over many years, resultant models may still be tenuous representations of actual porous media. For example, fluid flow models of porous media exceeding a few millimeters may require a lower resolution implementation to match currently available computational capabilities. As a result, fluid flow models based on porous media of a larger scale may not accurately reflect physical and chemical properties of the media. Accordingly, there is an impetus to improve the accuracy of fluid flow modeling, including, for example: improving image processing techniques to allow for higher resolution model input and model output, improving image processing techniques to allow for more accurate model input and model output, enhancing computational processing capability to reduce computational expense, enhancing computational processing capability increase modeling speed, increasing automation for iterative modeling steps, improving model capability for dynamic modeling of different fluid flow environments, improving model capability for dynamic modeling of larger fluid flow environments, and the like.

Consequently, there exists a need for further improvements in fluid flow modeling of porous media to overcome the aforementioned technical challenges and other challenges not mentioned.

### SUMMARY

In one embodiment, a method for pore network generation by one or more central processing units (CPU) is disclosed. The method for pore network generation by one or more central processing units (CPU) includes obtaining a representative pore network having a set of representative pore elements corresponding to a porous media sample. The selection of seed elements are randomized for the representative pore network. The seed elements are inflated to define a set of volumes and a set of buffer zones. The representative pore network is duplicated to produce a set of generated pore networks. The set of generated pore networks are stitched according to the set of volumes and set of buffer zones to produce a digital plug.

In another embodiment, a non-transitory computer-readable medium for pore network generation is disclosed. The non-transitory computer-readable medium for pore network generation includes computer-executable instructions that, when executed by one or more processors, cause one or more processing units to obtain a representative pore network having a set of representative pore elements corresponding to a porous media sample. The representative pore network is duplicated and stitched to fill a component of a digital plug. a set of buffer zones is defined. The representative pore elements are removed from the set of buffer zones. The set of buffer zones are repopulated using the representative pore network to produce a set of generated pore networks. The set of generated pore networks area stitched according to the set of volumes and set of buffer zones to produce the digital plug.

In another embodiment, an apparatus is disclosed. The apparatus includes a memory and one or more processors, the one or more processors configured to cause the apparatus to obtain a representative pore network having a set of representative pore elements corresponding to a porous media sample. A selection of seed elements are randomized for the representative pore network. The seed elements are inflated to define a set of volumes and a set of buffer zones. The representative pore network is duplicated to produce a set of generated pore networks. The set of generated pore networks are stitched according to the set of volumes and set of buffer zones to produce a digital plug.

### BRIEF DESCRIPTION OF THE DRAWINGS

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only example aspects and are therefore not to be considered limiting of its scope, may admit to other equally effective aspects.

FIG. 1A illustrates a ball and stick representation of an example pore network overlaid with the segmented micro-CT image of a porous media that it was extracted from, according to embodiments.

FIG. 1B illustrates an example set of high-resolution porous media image taken by a scanning instrument from a single rock sample and segmented for characterization, according to embodiments.

FIG. 2 illustrates an example core-flooding instrument for determining the physical and chemical characteristics of a porous media sample, according to embodiments.

FIG. 3 illustrates a pore network duplication and blending procedure, according to embodiments.

FIG. 4 illustrates an example workflow for constructing heterogeneous digital plugs, according to embodiments.

FIG. 5 illustrates an example heterogeneous digital plug generated from representative pore networks of sand packs, according to embodiments.

FIG. 6 illustrates an example composite network obtained using a combination of pore network duplication, stitching, and stochastic blending, according to embodiments.

FIG. 7A illustrates predicted relative permeability curves for primary drainage obtained using quasi-static pore network modeling simulations, according to embodiments.

FIG. 7B illustrates relative permeability curves for imbibition obtained using quasi-static pore network modeling simulations, according to embodiments.

FIG. 8 illustrates a set of example drill cuttings, according to embodiments.

FIG. 9 illustrates an example workflow for constructing digital plugs from drill cuttings, according to embodiments.

FIG. 10A-10H illustrates an example set of illustrations that show seeding and inflation of a digital core sample from drill cuttings, according to embodiments.

FIG. 11A illustrates an example composite network prior to using a combination of pore network duplication, stitching, and stochastic blending, according to embodiments.

FIG. 11B illustrates an example composite network obtained using a combination of pore network duplication, stitching, and stochastic blending, according to embodiments.

FIG. 12 illustrates an example composite network obtained using a combination of pore network duplication, stitching, and stochastic blending, according to embodiments.

FIG. 13 illustrates an example composite network obtained from a set of drill cuttings using a combination of pore network duplication, stitching, and stochastic blending, according to embodiments.

FIG. 14 illustrates a flow diagram of a method for pore network generation by one or more CPUs, according to embodiments.

FIG. 15 illustrates an example device for extracting pore networks, according to embodiments.

To facilitate understanding, identical reference numerals have been used, where possible, to designate identical elements that are common to the figures. It is contemplated that elements and features of one aspect may be beneficially incorporated in other aspects without further recitation.

### DETAILED DESCRIPTION

In the following, reference is made to aspects of the disclosure. However, it should be understood that the disclosure is not limited to specifically described aspects. Instead, any combination of the following features and elements, whether related to different aspects or not, is contemplated to implement and practice the disclosure. Furthermore, although aspects of the disclosure may achieve advantages over other possible solutions and/or over the prior art, whether or not a particular advantage is achieved by a given aspect is not limiting of the disclosure. Thus, the following aspects, features, and advantages are merely illustrative and are not considered elements or limitations of the appended claims except where explicitly recited in a claim(s). Likewise, a reference to “the disclosure” shall not be construed as a generalization of any inventive subject matter disclosed herein and shall not be considered to be an element or limitation of the appended claims except where explicitly recited in a claim(s).

The present disclosure relates to techniques for pore network extraction performed on porous media. Specifically, the techniques discussed herein may be implemented for use in generating accurate, high resolution pore networks representative of porous media that may be enabled for use in the pore network modelling. The porous media may comprise a digital rock sample, a core sample, a plastic sample, a tissue sample, or any other organic or inorganic sample having pore space ascertainable through imaging techniques.

A thorough grasp of fluid flow through pore networks of material with substantial pore space may be consequential to enhancing technical efficacy of fluid flow techniques in a wide range of industries. Models of fluid flow through a pores of a material may be used to describe physical and chemical characteristic of the material. Such models may help to highlight optimal usage for a certain porous material. In many cases, networks of pores within a material are extremely small, ranging from microscale to nanoscale in size. Techniques for characterizing these pore networks are hindered by the computational expense of modeling at a nanoscale. Often, to alleviate computational burdens, pore network modelling techniques use lower resolution image at the expense of model accuracy. Extrapolation errors caused by low resolution characterization may result in mischaracterization of physical and chemical characteristics of the porous material. Accordingly, ideal modeling of fluid flow through porous media would allow for rapid, accurate nanoscale pore network extraction that may be performed without inhibitive computational expense.

Aspects of the present disclosure provide techniques for generating digital representations of porous media (e.g., digital plugs) that replicate the key physical properties of porous media samples. Specifically, one or more processors may be configured to replicate and merge sub-networks that represent distinct physical formations (e.g., layering, facies, sub-structures) within of the sample to mimic the structure of the porous media sample. Additionally, the one or more processors may generate these digital plugs from cuttings of the porous media sample, which may be used to predict physical properties of large-scale bodies from which the porous media sample is derived when physical samples of the large scale bodies are unavailable.

Aspects of the present disclosure provide techniques for pore network duplication, stitching, and stochastic blending. Specifically, one or more processors may be configured to generate digital representations of porous media that reflect the local topology and heterogeneity of the entire sample. Additionally, aspects of the present disclosure may be parallelized to optimize computational performance.

Implementation of techniques for efficiently generating high-resolution pore networks as described herein may enhance pore network modelling functionality by reducing porous material characterization errors to the benefit of all users seeking a more comprehensive understanding of any given porous material.

### Introduction to Pore Network Modeling

Modeling techniques for fluid flow through porous media may illustrate both physical and chemical porous media properties. Models of porous media may be used to ascertain permeability, capillary pressure, fluid saturation, wettability, buoyancy, and the like to a greater degree of accuracy comparable to physical flooding of a porous media sample. Additionally, physical and chemical properties determined using pore network modeling techniques may be used to characterize in-situ fluid behavior as it travels through the porous media under a wide variety of wettability and flooding conditions. These conditions may not be accessible to users performing conventional physical flooding characterization techniques.

Permeability is the tendency of the porous media to allow liquids to flow through it. Capillary pressure is the pressure difference existing across the interface separating two immiscible fluids. Fluid saturation is the measurement of fluid present in the pore spaces of the porous media. Contact angle is a measured angle between a fluid-fluid or a fluid-gas interface at a point where it meets a solid surface. Wettability is the ability of a liquid to maintain contact with a solid surface. Wettability may vary depending on wettability conditions and the type of wetting liquid present in the porous media sample. For example, a water-wet medium may show a lower wetting affinity to the oil phase than an oil-wet medium, where higher or lower wetting is determined with respect to a given phase. In certain cases, the correlation between wettability and viscosity ratio may not be straightforward, as there may be water or oil wet conditions with similar viscosities.

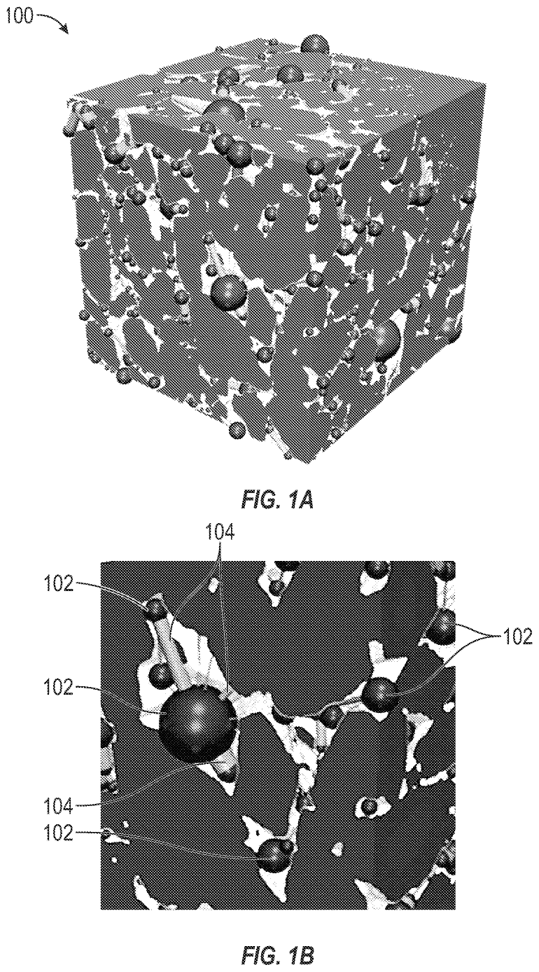

A modeled pore network is a practical description of a porous medium targeted for fluid flow modeling. FIG. 1A illustrates a ball and stick representation of an example section of a pore network overlaid with the segmented micro-CT image of a porous media that it was extracted from (e.g., porous sandstone). The section of the pore network describes the porosities of various size and shape present in that portion of the sandstone, and may be used to model fluid flow through those porosities for various wettability conditions. Three-dimensional (3D) portions of a pore network model may more accurately characterize the porous media sample either alone or in combination with other 3D portions of the pore network model.

Dynamic pore network models (e.g., of FIG. 1A) may be extracted from images of a targeted porous medium and used to model multi-phase fluid flow using physically-based displacement mechanisms (PBDMs) across pores defined in a pore network. PBDMs may represent an estimated displacement of a modeled fluid in response to movement of another fluid or gas within the pore network. As immiscible phases react with one another throughout the pore network during fluid flooding, PBDMs are induced where, for example, capillary pressure across a meniscus exceeds the wettability constraints on either phase. Fluid saturation, contact angle, buoyancy, and the like may also affect PBDMs throughout a pore network. By utilizing a pore network model extracted from a porous media sample, a user may be able to ascertain PBDMs through the porous media sample under a wide variety of wettability conditions in order to ultimately obtain, for example, useful permeabilities for a larger sample of the porous medium without degrading a porous media sample via repeated physical flooding.

To properly generate PBDMs at a pore scale for the targeted porous media, imaging may capture complex geometries of the targeted porous media at a resolution sufficiently high to retain acceptable accuracy. FIG. 1B illustrates an example set of high-resolution porous media image taken by a scanning instrument from a single rock sample and segmented for characterization. Pores may be defined as a complex polyhedron having at least a center 102 and spherical and effective diameters. Connective throats 104 between pores may also be defined. In many cases, image resolution may be in micrometers or nanometers to capture applicable pore detail. High-resolution pore models allow for accurate rendering of the fluid flow characteristics described above as ascertained at each pore and for each PBDM.

PBDMs may occur upon flooding or draining of a dynamic pore network model, where aqueous phase injection or removal is iteratively simulated through the pore network. Aqueous flooding and aqueous draining may be implemented in various modeled wettability conditions, where certain fluids are present prior to the start of a simulation. Wettability conditions may include at least water-wet, oil-wet, or mixed-wet conditions. During aqueous flooding, injected water may displace immiscible fluid preexisting in the pore network model. During aqueous draining, injected immiscible fluid may displace water preexisting in the pore network model. In certain cases, flooding and draining may be fluid flooding and fluid draining. In some cases, fluid may be oil.

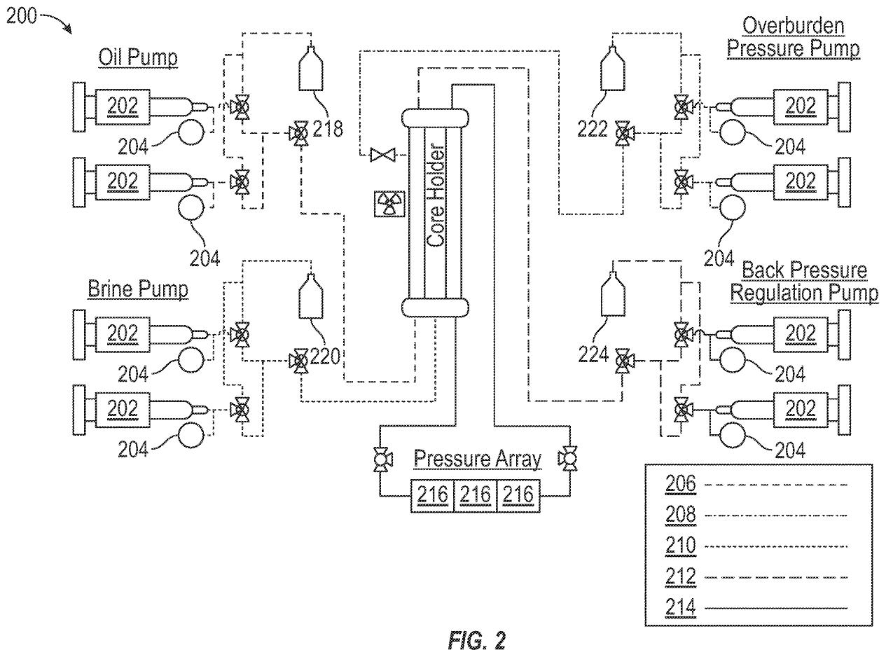

FIG. 2 illustrates an example core-flooding instrument for determining the physical and chemical characteristics of a porous media sample. Flooding or draining of a dynamic pore network model may be simulated based in part on scanned images of physical flooding implemented by the flooding instrument 200. In some cases, a porous media may undergo a core-flooding experiment to establish an irreducible water saturation, a residual oil saturation, or both. Core-flooding may be enabled by a set of pumps 202, rupture disks 204, pump lines 206-214, differential pressure transducers 216, and source buckets 218-222 working in tandem to flood a porous media sample loaded in a core holder. In some cases, a scanning instrument (e.g., a micro computed tomography (micro-CT) scanner) captures a dry reference image prior to flooding. Scanning occurs in a field of view defined within the core holder. In some cases, the porous media sample may be flooded with brine from bucket 220 via the brine tubing line 206 and scanned again to ensure that the porous media sample is fully saturated. Once the brine flooding is complete, the absolute permeability of the porous media sample may be obtained. The oil flooding may be performed alongside additional brine flooding. Any fluid expelled as a result of overburden pressure (i.e., pressure that compacts pore space and reduces permeability) may be transported via the confining fluid line 208 and collected in bucket 222. Any fluid expelled as a result of the flooding procedure may be transported via the effluent fluid line 212 and collected in bucket 224. In many cases, core sample pressure may be iteratively adjusted during flooding. Pressure may be recorded by one or more differential pressure transducers 216 coupled to the core holder via a transducer line 214.

Scanned images obtained from flooding procedures performed by the flooding instrument 200 may be used to extract a pore map representative of the porous media sample. The images may be processed to determine characteristics of fluid flow through the porous media sample. In many cases, the images may also be used to extract a representative pore network model.

Imaging of porous media is typically performed using micro-CT imaging. In many cases, commercial micro-CT scanners (e.g., Zeiss scanners) are available for imaging necessary to perform pore network modelling. Images of porous media taken by micro-CT scanners are at a sufficiently high resolution to create a microscale digital image of the porous media.

In the current state of the art, there exists a challenge of extracting porous media characteristics in a manner precise and repeatable to ensure the ultimate stability of future simulations. Currently, techniques for porous media characterization require lengthy step-wise processing known to incur undue computational expense and introduce instability to characterization of the porous media sample. As a result, users may not be able to rely on characterization output to simulate flow conditions in a useful way.

### Example Pore Network Duplication and Blending

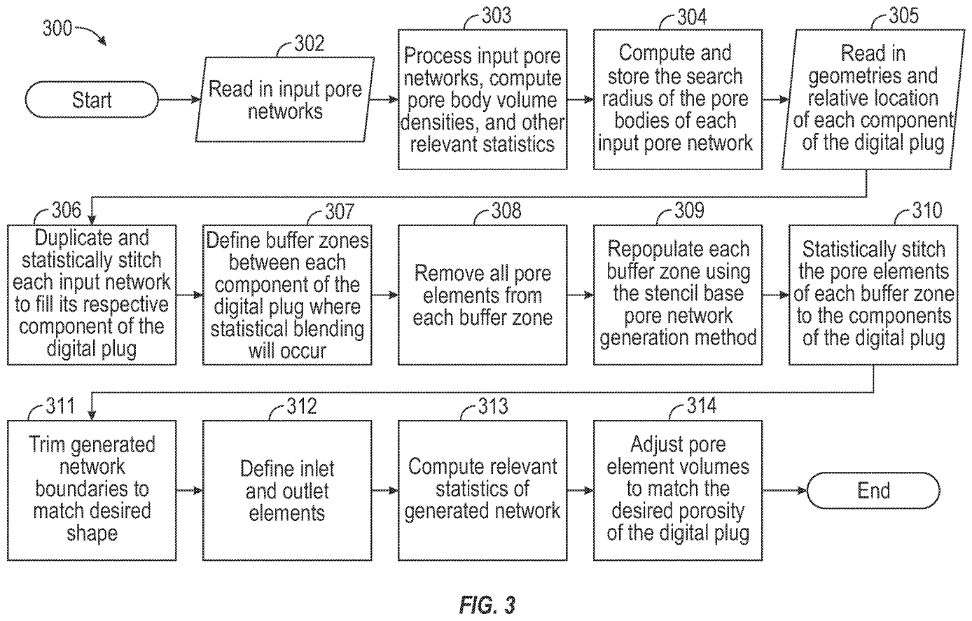

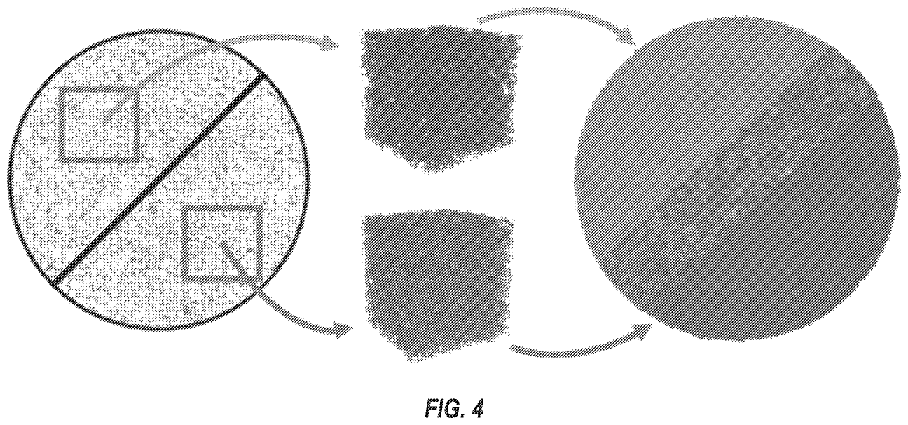

FIG. 3 illustrates a pore network duplication and blending procedure 300. FIG. 4 illustrates an example workflow for constructing heterogeneous digital plugs. In some cases, techniques for pore network duplication and blending may be available. One or more processors (e.g., one or more CPUs) may perform pore network duplication and blending procedures to generate a large-scale representation of a porous media sample (e.g., a digital plug). The pore network duplication and blending procedure that may be used to construct a representation of a porous media sample by one or more central processing units (CPU). Visualization of the procedure described in FIG. 3 is further illustrated in FIG. 4. In the procedure, one or more processors perform a pre-processing of the representative pore networks, local pore network duplication, stochastic stencil-based pore network blending, and post-processing of the heterogeneous digital plug. In many cases, the pre-processing step may be performed to read in and process the representative pore networks. In one example, during the local pore network duplication step, the processors may duplicate representative pore networks to fill their respective volumes within the heterogeneous digital plug and then merge the representative pore networks using a statistical stitching process. In another example, if the samples are sufficiently homogeneous, a stochastic stencil-based pore network generation routine may be used in place of this pore network duplication step. Next, the one or more processors may employ a stencil-based pore network generation method to blend each component of the heterogeneous digital plug. Finally, the resulting pore network is post-processed to match the desired geometry, define inlet and outlet pore elements, and adjusted to match the desired porosity data.

At operation 302 of the network duplication and blending procedure, a set of run parameters may be read into the program. These run parameters may include the desired physical dimensions of the heterogeneous digital plug, the relative locations and volume geometries of each component of the digital plug, as well as the stencil depth limit (e.g., the maximum search depth to consider when defining each pore body's stencil) to be used while performing the stencil-based pore network blending. Additionally, the dimensions of the inlet and outlet buffer zones and excess regions used to define the inlet and outlets of the generated pore network may be provided. Often, the primary inputs to stencil-based stochastic pore network generation are the representative pore networks targeted for representation. The procedure presented here replicates the representative pore networks and allows one or more processors to construct porous networks independent of the porous media sample targeted for replication.

At operation 303, after each representative pore network is read into the program, the one or more processors perform set of pre-processing steps to compute relevant statistics and properties of the input pore network. In one example, the porosity and clay content of each representative pore network are computed and stored. In one example, the pore body density of representative pore network and the volume percentage of the pore network that is occupied by its pore bodies may be determined for the representative pore network. Symbolically, if the total volume of the representative pore network is Vᵣ, and the set of its pore bodies is represented by Ωᵣ, then the representative pore network's pore body density, Dᵣ is computed as:

$${D}_{r} = \frac{{\sum }_{i ∈ Ω} {v}_{i}}{{V}_{r}}$$

where νᵢ represents the volume of pore body i.

Consistency with these pore body densities may be used as the primary stopping criteria for the stencil replication process used during the pore network blending step described below.

In certain cases, pore elements that lie on the surface of each representative pore network are identified and deleted. By removing these elements, the new surface of the pore network may consist of pore elements with deficient coordination numbers. This deficiency allows for pore throat connections to be added between neighboring duplicated pore network, and established the buffer zones where stochastic blending may be performed. The remaining pore elements of each pore network may comprise a sample set, the collection of pore elements to be replicated by the one or more processors to create a heterogeneous digital plug. After each sample set has been determined, a map between each pore body, and its attached pore throats, may be constructed and stored. These maps may allow each stencil of each pore body to be computed efficiently during the stencil duplication step.

At operation 304, the one or more processors then compute and store a search radius of each pore body within the sample set for use when statistical stitching is performed. The search radius may represent the maximum distance that can exist between two pore bodies for a pore throat connection to be added between them. The search radius may be computed as an arithmetic mean of the largest and average distance between a pore body of the sample set and the pore bodies that it shares a pore throat with. In this way, the search radius of each element is unique and reflects the local topology of the representative pore network. During this process the one or more processors also accumulate and store the average spacing between each connected pore body of the sample set.

At operation 305, read in relative location of the components of the digital plug. The domain of the digital plug is partitioned to indicate where different regions of the generated pore network that are to be stitched or blended, as will be described in further detail.

At operation 306, statistical stitching begins by the processors defining a stitch queue consisting of pore bodies of the generated network whose coordination number is less than their corresponding defining element of the input network. Each element of the stitch queue is then assigned a desired coordination number based on the coordination number of its corresponding defining element. The processors then select a pore body from the stitch queue and add pore throat connections between it and its neighboring pore bodies in the following way. In some cases, the processors may first identify the pore bodies of the stich queue that do not already share a pore throat connection with the selected pore body and are within its precomputed search radius. The processors then rank this set of pore bodies using a weighted average of the distance between them, and the absolute difference between their spherical radii. In other words, the processors prioritize connecting pore bodies that are close to each other and have similar radii. The processors then sequentially connect the selected pore body with its highest-ranking neighbors until either its desired coordination number is reached, or a connection between every element within its search radius has been added. These connections are established by duplicating pore throats from the representative pore network that preserve the aspect ratios of both elements.

In some cases, pᵢ may represent the pore body of the representative pore network that the selected pore body was duplicated from, and Ψ′ᵢ may represent the set of pore throats that are connected to it. Further, tᵢⱼ∈LΨᵢ, may denote an arbitrary pore throat that connects pᵢ with pⱼ, the second pore body of the representative pore network that tᵢⱼ is connected with. The element of Ψ′ᵢ may be copied to define a pore throat connection between the selected pore throat and its highest-ranking neighbor is then determined by the following equation:

$$t = {min}_{{t}_{ij} ∈ Ψ} \vert R - {R}_{j} \vert$$

where Rⱼ and R are the spherical radii of pⱼ and the highest-ranking neighbor, respectively. After t has been determined, the processors then add a pore throat connection between the selected pore body and its highest-ranking neighbor by duplicating t and updating its length information to reflect the relative positions of these two pore bodies. The coordination number of each pore body is then incrementally increased. A pore body may be removed from the stitch queue when its coordination number equals its desired value. This process may be repeated on every element of the stitch queue until every viable pore throat connection has been established.

At this point, the generated pore network (e.g., the heterogeneous plug) may consists of an optimal number of both pore bodies and pore throat connections. In the post-processing step, the processors fit the generated pore network to its desired shape and dimensions, create boundary elements, and match its porosity with the representative pore network.

The one or more processors then fill the geometries of each component of the heterogeneous digital plug by repetitively duplicating the sample set of the representative pore network that is assigned to it. The one or more processors may extend these geometric boundaries to guarantee that the geometry is completely filled during the duplication step. The space between each duplicated sample set is determined using a fraction of the average distance between connected pores. Often, the orientation of each duplication is independent of this process but must be chosen to ensure an even spacing between its duplicated neighbors. After the geometry of a component has been fully filled with duplicated sample sets, the one or more processors trim the boundaries to match its desired dimensions.

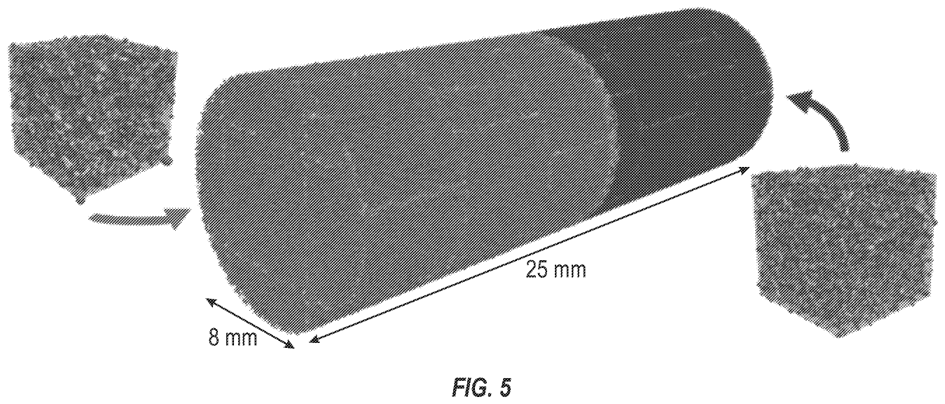

FIG. 5 illustrates an example heterogeneous digital plug generated from representative pore networks of sand packs. The heterogeneous digital plug is shown generated with two components with pore throat connections added during the stitching process highlighted. By construction, pore bodies that lie on the surface of each duplicated sample set may have coordination numbers that are less than their desired value. To merge each sample set together, the one or more processors use these coordination number deficiencies and employ a statistical stitching process to add well characterized pore throat connections between each duplicated sample set.

After each component of the heterogeneous digital plug has been filled using the local pore network duplication process, the one or more processors stochastically blend them together using a stencil replication procedure.

The one or more processors may perform the stencil replication procedure according to the following steps. First, the processors populate the generated pore network by randomly selecting pore bodies from the sample set and computing random positions within the desired physical dimensions of the generated network to place them during a stencil replication process. After a pore body and its location have been determined, the processors may check if a pore body's placement and spherical radius would overlap with previously generated pore bodies. If no overlaps exist, then the selected pore body is added to the generated network, and the processors identify the pore body as a seed element for the duplicated stencil. A breadth-first search (BFS) is performed by the processors to identify the surrounding layer of pore elements of the sample set that are connected to the seed element. This set of elements initially populates the add queue of the duplicated stencil. Each pore body of the add queue is then evaluated, and its relative position to the seed element within the generated pore network is computed. If the selected element of the add queue lies inside the domain of the generated pore network, and does not overlap with previously placed pore bodies, then it is added to the generated pore network. A BFS is then performed to identify the pore bodies of the sample set that are connected to the selected pore body. If an element of this layer has already been copied into the duplicated stencil, then the pore throat that connects them in the sample set is also duplicated in the generate pore network. If a connected element has not already been added, and the layer depth limit has not been reached, then it is inserted into the add queue. The size of the add queue increases until each viable element of the sample set, within the layer depth search limit, has been added to the add queue. After each pore-element of the add queue has been accessed a new seed element is selected from the sample set and the process is repeated to stochastically duplicate the next stencil.

Pore bodies with a large coordination numbers are more likely to be duplicated since they belong to a larger number of stencils. To prevent oversampling these subsets of the representative pore network, the processors temporarily remove pore bodies from the sample list after they have been duplicated in the generated pore network. These pore bodies are periodically repopulated back into the sample set after a user defined percentage of the original sample set has been duplicated.

Termination of the stochastic pore network stencil replication process may be determined by one or more processors using the pore body volume of the generated pore network. The one or more processors may define the desired pore body volume, ρ_{g}, to be the pore body density of the representative pore network multiplied by the desired volume of the generated pore network (ρ_{g}=Dᵣ·V_{g}). After a stencil has been duplicated the pore body volume of the generated pore network is computed and compared against the desired pore body volume. When the pore body volume of the generated pore network is larger than ρ_{g}, the stochastic pore network stencil replication process is stopped, as no more pore bodies are required to define the generated pore network.

After the stencil duplication step has been completed, a sufficient number of pore bodies have been replicated. In the statistical stitching process, the processors may add connections between each duplicated stencil and thereby may add a sufficient number of pore throats to the generated pore network. Notably, after stochastic stencil duplication, throat connections between each duplicated stencil do not exist, and pore bodies on the outer layer of each stencil have coordination numbers that are less than the element of the representative pore network from which they were duplicated.

At operation 307, the geometries of buffer zones between neighboring components may be identified. At operation 308, the previously duplicated pore elements within them are removed. The dimensions of these buffer zones may be either user defined, or their widths may be computed as a multiple of the average distance between the pores of each component. The buffer zone is then populated.

At operation 309, the generated pore network may be repopulated in a cuboid domain that is slightly larger than the desired physical dimensions that were read in. This is done to ensure that the generated pore network faithfully recreates the internal structure of the representative pore network along its boundaries. In many cases, the processors may remove elements of the generated pore network that lie outside of its desired domain and shape. For example, if the desired pore network should be cylindrical in shape, the distance of each pore body from the center of the generated pore network and the center of the cylinder is computed. If the elements lie outside the radius of the desired cylindrical shape then the elements and their attached pore throats are removed from the network.

At operation 310, the pore elements of each buffer zone are statistically stitched to the components of the digital plug. At operation 311, the processors then trim generated network boundaries to match desired shape and to define boundary elements.

At operation 312, the inlet and outlet elements are defined. To define inlet pores, outlet pores, and buffer zones a mid-plane that is perpendicular to the direction of flow is defined by the processors at the desired location of the inlet. Any pore throat that intersects this mid-plane is classified as an inlet pore throat, and all pore elements that lie within the excess region (i.e., between the mid-plane and the outer boundary of the generated pore network) are removed. If more than one inlet pore throat is attached to the same pore body, then the one with the largest spherical radius is kept. A similar process is used to define the outlet boundary. In certain cases, the seed element for each duplicated stencil may be chosen randomly from the sample set of each of the neighboring components. This may allow the buffer zone to be stochastically filled with pore elements from each component of the representative pore network. Termination of the stochastic pore network stencil replication process may be determined using the average of each components pore body volume. Afterwards, the one or more processors employ a statistical stitching process described herein to add well-characterized pore throat connections between each duplicated sample set.

At operation 313, relevant statistics are computed. At this point, the heterogeneous digital plug may consist of an optimal number of both pore bodies and pore throat connections. At operation 314, the one or more processors may fit the generated pore network to its desired shape and dimensions, create boundary elements, and match its porosity with representative pore networks. According to certain aspects, the porosity of the heterogeneous digital plug may be determined. First, if a desired porosity value for the digital plug is known, then the value can be directly compared against the computed porosity of the heterogeneous digital plug. Alternatively, if a desired porosity is unknown, then a weighted average of each representative pore network's porosity can be used. In one case, if the void volume percentage or clay content of the generated network does not match their desired values, then a small adjustment may be performed by the one or more processors to each pore element so that the desired porosity is achieved. In certain cases, φᵣ and φ_{g} may represent the porosity of the representative and generated pore network, respectively. Accordingly, the one or more processors may update the volume of each pore element to be α. φᵣ·ν/φ_{g}, where ν is the current volume of the pore element and a is a random variable ranging from 0.5 to 1.5 in value. Afterwards, the summation of each pore elements volume will sum to a value that is close to φᵣ.

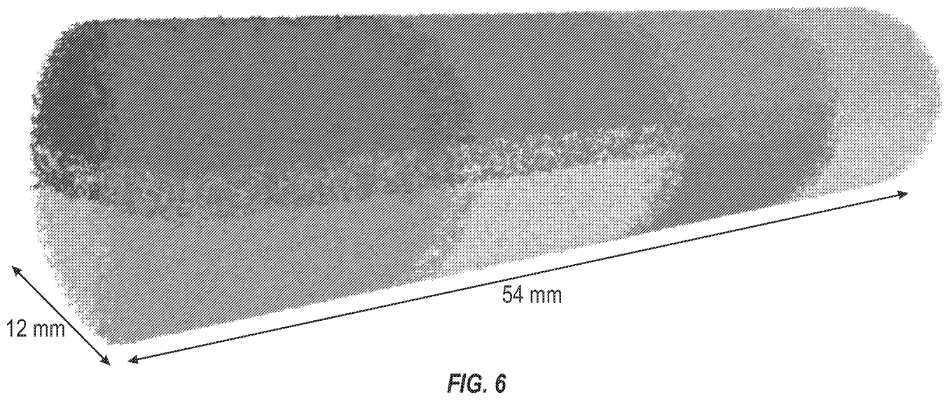

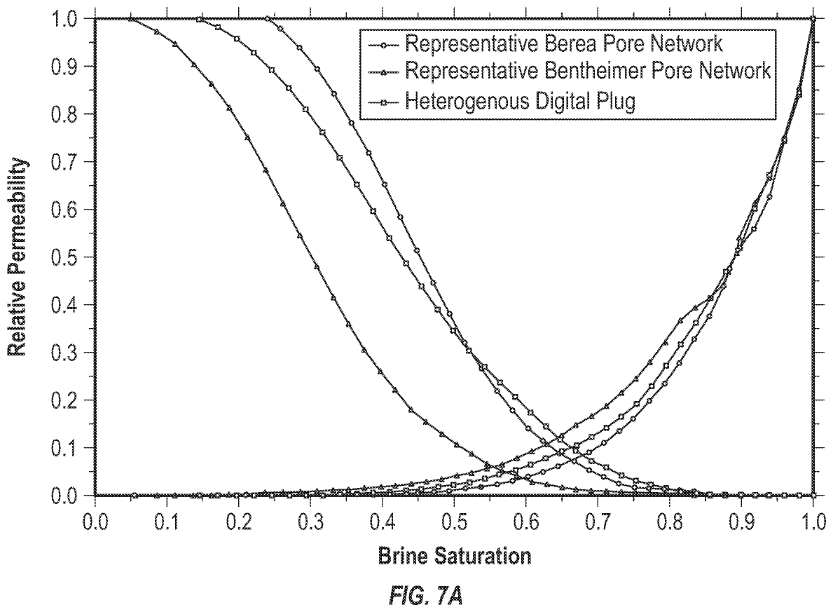

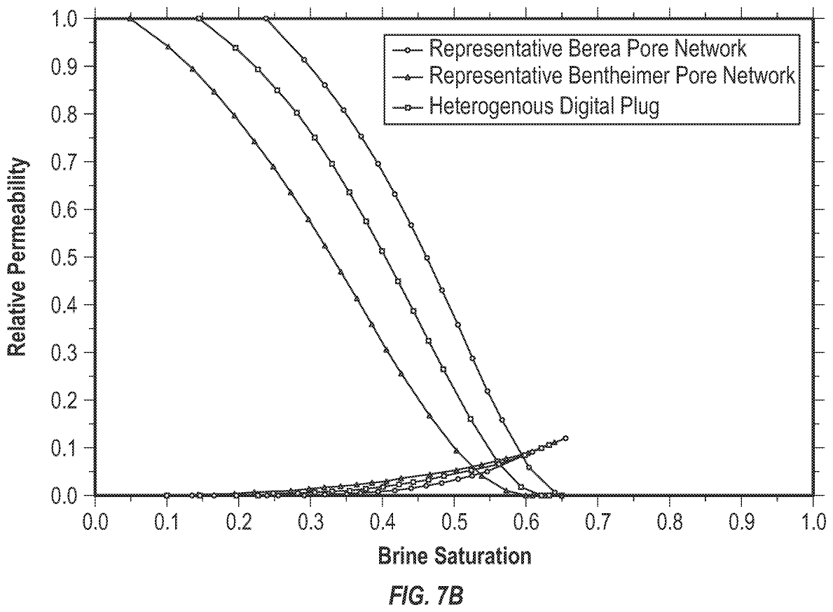

FIG. 6 illustrates an example composite network obtained using a combination of pore network duplication, stitching, and stochastic blending. The visualization of a heterogeneous digital plug that was obtained using representative pore networks of Berea and Bentheimer sandstones. To demonstrate the properties of pore networks generated with this method, predictions of primary drainage and imbibition relative permeability curves for this heterogeneous digital plug are provided in FIG. 7A and FIG. 7B, respectively. For comparison, the relative permeability curves of the Berea and Bentheimer pore networks from which the digital plug was generated are also provided in FIG. 7A and FIG. 7B.

### Aspects Related to Generating a Digital Plug using Drill Cuttings

There exists a challenge of predicting fluid flow through porous media in a manner precise and repeatable to ensure the ultimate stability of future simulations. Currently, techniques for two-phase fluid flow prediction require lengthy step-wise processing known to incur undue computational expense and introduce instability to characterization of the porous media sample. As a result, users may not be able to rely on characterization output to simulate flow conditions in a useful way.

Fluid flow modelling through porous media is often utilized to enhance petroleum resource development. In recent years, global demand for energy resources has mobilized development of petroleum reservoirs as targets for hydrocarbon extraction. The geological formations that comprise these hydrocarbon reservoirs are ultra-tight shale formations resistant to primary petroleum extraction techniques. A matrix of an ultra-tight shale reservoir may be characterized by low permeability and low porosity. To extract hydrocarbons from the ultra-tight shale matrix, secondary and tertiary petroleum extraction techniques seek to maximize oil production through the microscale pore networks that comprise a substantial amount of the porosity in the shale matrix.

A robust understanding of fluid flow through microscale pore networks of unconventional reservoirs may be consequential to extracting the trillions of barrels of oil still housed in shale formations globally. Models of fluid flow through a pore network that describe permeability, capillary pressure, fluid saturation, and wettability may help to elucidate specific steps to be taken during resource development to optimize petroleum production. Even so, techniques for characterizing these microscale pore networks are hindered by the computational expense of modeling sub-resolution pore network and extrapolation errors caused by unstable characterization of pore geometries.

As discussed above, ideal modeling of fluid flow through porous media would allow for high resolution imaging of a macro-sized porous media sample. In a case where the porous media sample is, for example, a cylindrical core sample of a rock having a length of six inches and a diameter of one inch, the core sample is likely to have porosity and permeability that vary across its length and width. This is common in core samples, and especially in core samples representative of ultra-tight oil formations. Geological processes that form certain oil-bearing rocks can produce heterogeneous morphological features in the rock that may be present even at a nanometer scale. This is especially true for oil bearing carbonate rocks, which contain micro-porosities that contribute significantly to the overall porosity of the rock. These nanoscale morphological features may affect the pore network of the core sample, altering the porosity and permeability throughout a core sample. Thus, accurate characterization of fluid flow through a core sample may depend on nanoscale resolution sufficient to detect heterogeneous properties of a pore network.

According to aspects of the present disclosure, the pore network extraction procedure may be performed by a processing system architecture comprising at least one or more CPUs operating independently or in combination with one or more graphics processing units GPUs. The one or more CPUs and/or the one or more GPUs may perform the stitching procedures according to a non-transitory computer readable medium that causes the one or more CPUs and/or the one or more GPUs to perform any and all steps of the stitching procedure. Each of the one or more CPUs may be utilized in combination with a memory having the computer readable medium stored thereon. Each of the one or more CPUs be utilized in combination with one or more processors. Each of the one or more processors may be parallel processors. Each of the one or more GPUs may be utilized in combination with a memory having the computer readable medium stored thereon. Each of the one or more GPUs be utilized in combination with one or more processors. Each of the one or more processors may be parallel processors. Each of the CPUs and the GPUs may operate independently, or may operate using a message passing interface (MPI) enabling communication between one or more parallel processors for performing the imagine stitching procedure. This may include CPU-CPU communication, CPU-GPU communication, and/or GPU-GPU communication.

Numerical computation from high-resolution 3D micro-tomographic images of rocks, also known as Digital Rock Technologies (DRT), has the potential to more accurately predict the underlying petrophysical properties and macroscopic flow behavior of fluids within such porous media. The first component of DRT is image processing of micro-CT images, which may entail processing of images obtained by micro-CT scanner in the lab. Ideally, DRT may accurately and efficiently render and process the obtained image datasets, which may allow a user to obtaining reliable digital replicates that are in one-to-one correspondence to the rock samples. However, in the current state of the art, DRT is limited to samples with simple structure and mineralogy, and may have low computational efficiency, ultimately making DRT less than desirable to process large image datasets (high resolutions and/or large physical sample sizes). Additionally, the majority of existing attempts require continuous end-user input and interaction for each case. This prevents scaling out by preventing automated execution and batch processing of a number of cases. There also exists a challenge in processing multi-mineral rocks that are presented using grayscale values of different minerals in micro-CT images, because those values are often very similar.

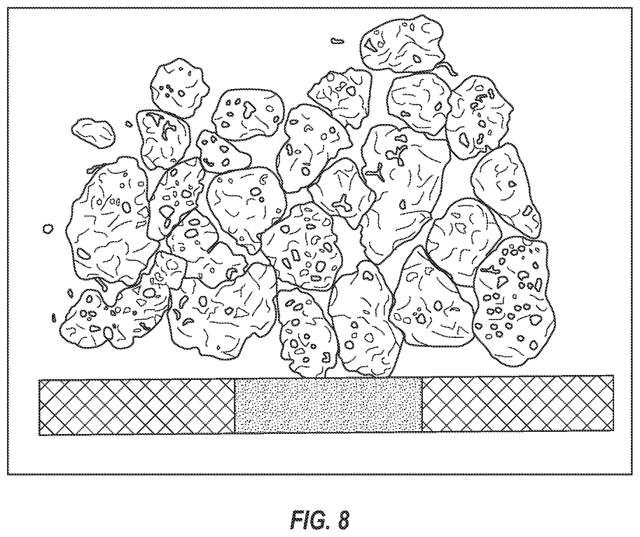

Example drill cuttings are illustrated in FIG. 8. Drill cuttings are fragments of a porous media sample (e.g., a rock sample) generated during well drilling. In situations where core output is low, such as when drilling through weakly cemented reservoirs with high porosity and permeability, collecting cutting samples becomes necessary. However, the information obtained from analyzing drill cuttings is limited. Generally, cutting analysis is used to supplement routine and special core analysis in order to acquire more detailed geological and petrophysical information when core data is unavailable. However, because the drill cutting are irregular and lack coordination with any specific geologic facies, information as available in the current state of the art is subject to error.

Having an efficient cuttings analysis technology may decrease drilling costs and time. As an example, partially replacing 75% of core drilling with reverse circulation (RC) drilling (which involves cuttings sampling) could lead to substantial financial and time savings.

There are numerous issues with utilizing drill cuttings in DRT. In one example, drill cuttings are typically small, irregularly shaped, and fragmented, which makes it difficult to obtain a representative volume or an accurate representation of the porous media microstructure. In another example, sample preparation may be difficult because proper sample preparation is crucial for DRP analysis. Cleaning, mounting, and polishing cuttings can be difficult due to their small size and irregular shape. This can lead to inaccuracies in imaging and simulations. In another example, high-resolution 3D imaging techniques like X-ray micro-CT are often used in DRT studies. However, drill cuttings may require even higher resolutions to capture the intricate pore structures accurately, which may be challenging and time-consuming. In another example, obtaining a representative sample from drill cuttings may be challenging, as they may not accurately represent the entire formation. The small size of cuttings can limit the ability to detect and analyze macroscopic features or variations in the porous media. In another example, geological formations may be highly heterogeneous, with varying mineralogy, porosity, and permeability. Accurately capturing this heterogeneity in a small, fragmented sample of drill cuttings can be difficult. In another example, the drilling process can cause mechanical damage to the cuttings, including crushing, smearing, or alteration of the original rock fabric. This can affect the accuracy of DRT analysis.

Aspects of the present disclosure provide techniques for emulating physical properties (e.g., petrophysical properties) of an input pore network to mimic certain physical structures by replicating the support of its pore-bodies. Specifically, existing pore-bodies may be sampled from the input network and randomly placed within the desired dimensions of the generated pore network. Then, using the connectivity information of the input pore-body, several layers of surrounding pore-elements may be added to the generated network. In this way, the local topology of the input network may be preserved within the generated pore network. In certain cases, the placement of each pore-body and the replication of their support can be performed by one or more processors independently with limited communication between threads. After the generated pore network has an equivalent density of pore bodies as the input network, additional pore throats may be added to provide connections between each replicated support. Placement of these pore throats is determined using the coordination numbers of the input network, and the geometrical information of the neighboring pore throats of each pore-body.

Where pore network generation is applied to drill cuttings, the volumes within the digital plug are discretized. When extracting a porous media sample from drill cuttings, the processors will need to account for the lack of coordinates associated with each drill cutting. The lack of coordinates for each drill cutting raise an additional issue of placement of the drill cuttings within the digital plug. Because placement of drill cutting information within the digital plug cannot be based on an actual coordinates associated with the porous media, one or more processors grab a random point in space inside of the discretization and define that point as a seed to generate a digital facies associated with that cutting. Multiple seed points may be generated to create a digital facies map that is able to reflect the petrochemical properties of the drill cuttings. In some cases, the processors may apply an inflation step to each seed point to fill the volume. During the inflation step, the processors may randomly assign volumes for each drill cutting to fill the digital plug. After the inflation step, the processors may define interfaces between each drill cutting volume within the digital plug and resolve those interfaces according to the methods described above.

Additionally, pore network extraction performed by processors operating in sequence may be unable to support the computational load associated with nanoscale pore networks. Techniques implemented to address issues with resolution sufficiency may also address issues arising from the computational expense of high-resolution imaging.

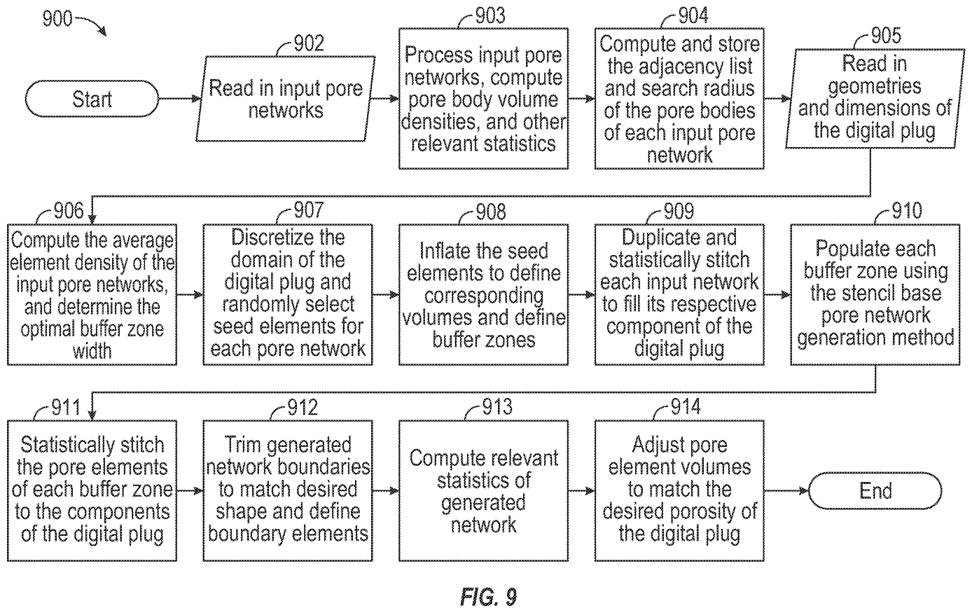

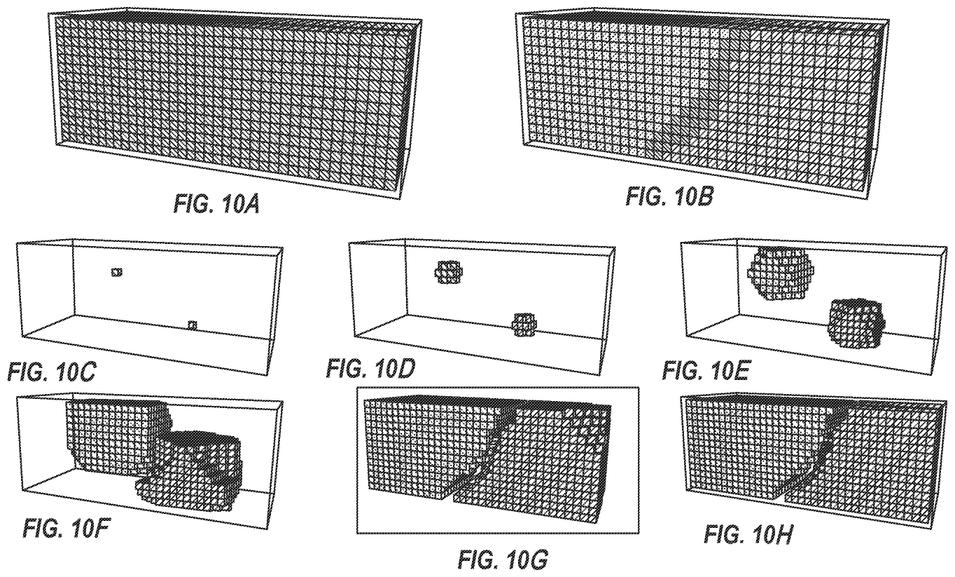

FIG. 9 illustrates an example workflow for constructing digital plugs from drill cuttings. According to certain aspects, construction of a generated pore network using drill cutting may be achieved according to steps performed by one or more processors. FIGS. 10A-10H illustrates an example of seed assignment and inflation from the assigned seed as it may occur during one realization of the workflow described in FIG. 9. At operation 902, a pre-processing step is performed to read in and process the representative pore network to define the sample set. At operation 903, the processors process the input pore networks, compute pore body volume densities, and any other relevant statistics. At operation 904, the processors compute and store the adjacency list and the search radius of the pore bodies of each input pore network, and, at operation 905, read in geometries and dimensions of a digital plug having a target size (e.g., a size comparable to a porous media sample). At operation 906, the processors then compute the average element density of the input pore networks, and determine the optimal buffer zone width.

At operation 907, as for each input pore network, the processors will discretize the domain of the digital plug and randomly select seed elements for each pore network. As shown in FIG. 10A, the processors may uniformly discretize a slightly larger volume than the desired digital core. As shown in FIG. 10C, the processors may select seed elements (e.g., voxels) randomly.

At operation 908, the processors inflate the seed elements to define corresponding volumes and define buffer zones. As shown in FIG. 10D the processors may assign random volumes and locations of digital plugs to input pore networks. As shown in FIGS. 10E-10G, the processors may inflate the volumes from the seed elements to assign volumes to each input pore network. As shown in FIG. 10H, the processors may identify an interface region between each dedicated pore volume.

At operation 909, duplicate and statistically stitch each input network to fill its respective component of the digital plug having a target size. As shown in FIG. 10A, the processors may duplicate input pore networks to fill assigned volumes and use stitching to fill the interface region between them. As shown in FIG. 10B, the processors may duplicate input pore networks to fill assigned volumes and use stochastic blending to fill the interface region between them. Duplication and statistical stitching may be further understood with respect to at least FIG. 3 and FIG. 4, described above.

At operation 910, using the stencil-based pore network generation, as shown in operation 310 of process 300, the processors populate each buffer zone. At operation 911, statistically stitch the pore elements of each buffer zone to the components of the digital plug. At operation 912, the processors then trim generated network boundaries to match desired shape and to define boundary elements. At operation 913, and as shown in operation 313, relevant statistics are computed. At operation 914, the pore elements are adjusted to match the desired porosity of the digital plug, and pore network construction ends. The processors output a digital plug having properties representative of target drill cuttings.

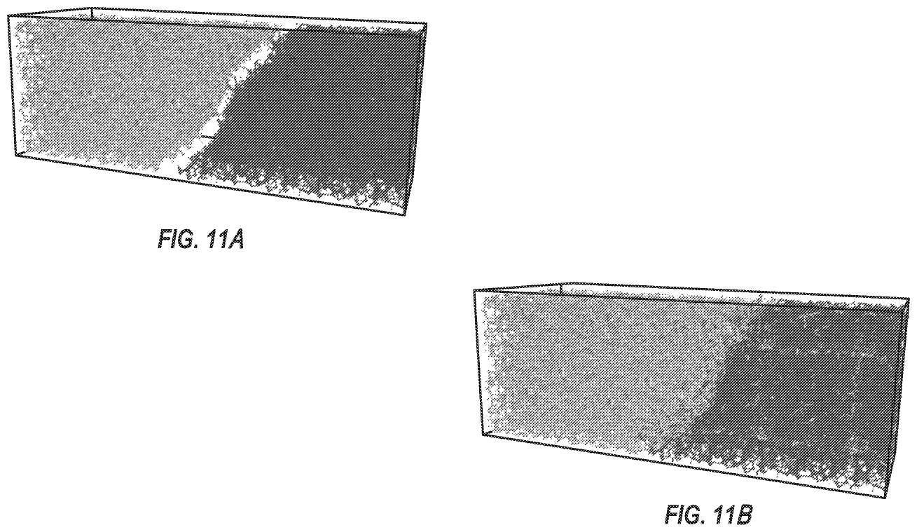

FIG. 11A illustrates an example composite network prior to using a combination of pore network duplication, stitching, and stochastic blending. FIG. 11B illustrates an example composite network obtained using a combination of pore network duplication, stitching, and stochastic blending. According to certain aspects, after the processors define an interface, the processors may replicate the input pore networks to occupy their designated volumes. Example volumes are illustrated as light and dark grey, with a buffer zone in between. If applicable, a stochastic stencil-based pore network generation routine may be used to replicate the input pore networks to occupy the buffer zones. Stochastic blending is employed by the processors to occupy the interface area (e.g., the buffer zone) between duplicated volumes and interfaces. In some cases, stitching between each duplicated pore networks may occur during this step, such that throats are added away from the interface region.

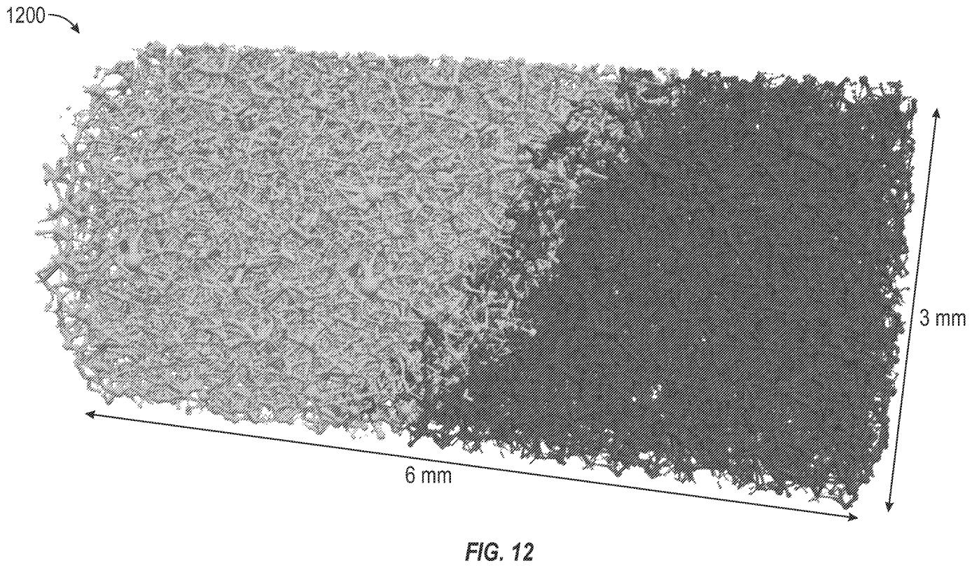

During a post-processing step (similar to the post-processing step described with respect to FIG. 3 and FIG. 4), the processors may fit the generated pore network to its desired shape and dimensions, create boundary elements, and match the porosity with the input pore networks. FIG. 12 illustrates pore network generated from drill cuttings after this post-processing step using a combination of pore network duplication, stitching, and stochastic blending.

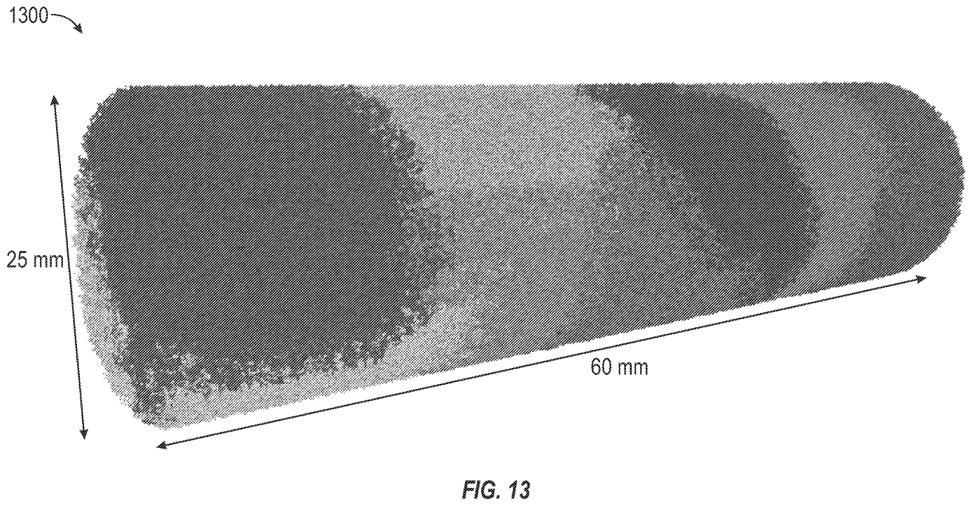

FIG. 13 illustrates an example composite network obtained from a set of drill cuttings using a combination of pore network duplication, stitching, and stochastic blending. After the workflow is complete a complete plug may be stitched from numerous drill cuttings to create a digital plug having physical characteristics corresponding the physical characteristics of the drill cuttings.

### Example Methods

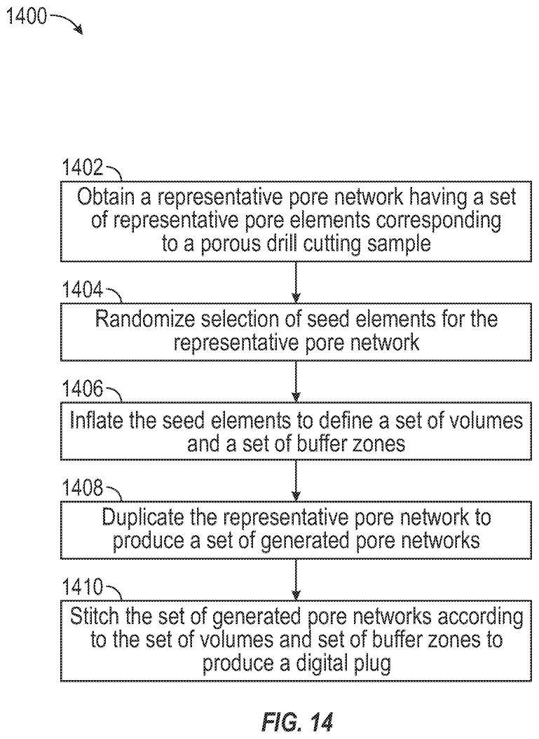

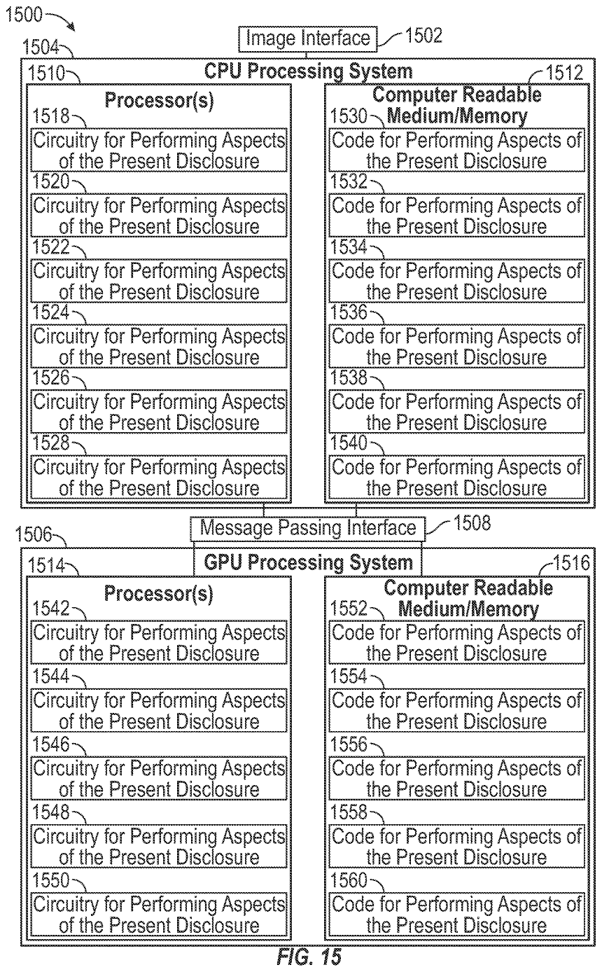

FIG. 14 depicts a method 1400 for pore network generation by one or more CPUs, such as the CPUs of the device 1500 of FIG. 15.

At operation 1402, one or more CPUs obtain a representative pore network having a set of representative pore elements corresponding to a porous drill cutting sample.

At operation 1404, one or more CPUs randomize selection of seed elements for the representative pore network.

At operation 1406, one or more CPUs inflate the seed elements to define a set of volumes and a set of buffer zones.

At operation 1408, one or more CPUs duplicate the representative pore network to produce a set of generated pore networks.

At operation 1410, one or more CPUs stitch the set of generated pore networks according to the set of volumes and set of buffer zones to produce a digital plug.

In one aspect, method 1400, or any aspect related to it, may be performed by an apparatus, such as device 1500 of FIG. 15, which includes various components operable, configured, or adapted to perform the method 1400. Device 1500 is described below in further detail.

Note that FIG. 14 is just one example of a method, and other methods including fewer, additional, or alternative steps are possible consistent with this disclosure.

### Example Device

FIG. 15 depicts aspects of an example porous media device 1500. In some aspect, the device 1500 comprises one or more CPUs, one or more GPUs, or both as described above with respect to FIG. 4.

The device 1500 includes a CPU processing system 1504 coupled to an image interface 1502 (e.g., a user interface or and/or an image generator such as a commercial micro-CT scanner). The CPU processing system 1504 may be configured to perform processing functions for the device 1500, including pore network extraction performed by the device 1500.

The CPU processing system 1504 includes one or more processors 1510. The one or more processors 1510 are coupled to a computer-readable medium/memory 1512 via a bus. The one or more processors 1510 and the computer-readable medium/memory 1512 may communicate with the one or more processor 1514 and the computer-readable medium/memory 1516 of the GPU processing system 1506 via a message passing interface (MPI) 1508. In certain aspects, the computer-readable medium/memory 1512 is configured to store instructions (e.g., computer-executable code) that when executed by the one or more processors 1510, cause the one or more processors 1510 to perform the method 1400 described with respect to FIG. 15, or any aspect related to it. Note that reference to a processor performing a function of device 1500 may include one or more processors performing that function of device 1500.

In the depicted example, computer-readable medium/memory 1512 stores code (e.g., executable instructions) 1530-1540 for performing techniques described herein, according to aspects of the present disclosure. Processing of the code 1530-1540 may cause the device 1500 to perform the method 1400 described with respect to FIG. 14, or any aspect related to it.

The one or more processors 1510 include circuitry configured to implement (e.g., execute) the code stored in the computer-readable medium/memory 1512, including circuitry 1518-1028 for performing techniques described herein, according to aspects of the present disclosure. Processing with circuitry 1518-1528 may cause the device 1500 to perform the method 1400 described with respect to FIG. 14, or any aspect related to it.

Various components of the device 1500 may provide means for performing the method 1400 described with respect to FIG. 14, or any aspect related to it.

The device 1500 includes a GPU processing system 1506. The GPU processing system 1506 may be configured to perform processing functions for the device 1500, pore network extraction performed by the device 1500.

The GPU processing system 1506 includes one or more processors 1514. The one or more processors 1514 are coupled to a computer-readable medium/memory 1516 via a bus. The one or more processors 1514 and the computer-readable medium/memory 1516 may communicate with the one or more processor 1510 and the computer-readable medium/memory 1512 of the CPU processing system 1504 via an MPI 1508. In certain aspects, the computer-readable medium/memory 1516 is configured to store instructions (e.g., computer-executable code) that when executed by the one or more processors 1514, cause the one or more processors 1514 to perform the method 1400 described with respect to FIG. 14, or any aspect related to it. Note that reference to a processor performing a function of device 1500 may include one or more processors performing that function of device 1500.

In the depicted example, computer-readable medium/memory 1516 stores code (e.g., executable instructions) for performing certain functions according to aspects of the present disclosure 1552-1560. Processing of the code 1552-1560 may cause the device 1500 to perform the method 1400 described with respect to FIG. 14, or any aspect related to it.

The one or more processors 1514 include circuitry configured to implement (e.g., execute) the code stored in the computer-readable medium/memory 1516, including circuitry for performing certain functions according to aspects of the present disclosure 1542-1550. Processing with circuitry 1542-1550 may cause the device 1500 to perform the method 1400 described with respect to FIG. 14, or any aspect related to it.

Various components of the device 1500 may provide means for performing the method 1400 described with respect to FIG. 14, or any aspect related to it.

### Example Aspects

Implementation examples are described in the following numbered clauses:

Aspect 1: A method for pore network stitching by one or more central processing units (CPU), comprising obtaining a representative pore network having a set of representative pore elements corresponding to a porous drill cutting sample, randomizing selection of seed elements for the representative pore network, inflating the seed elements to define a set of volumes and a set of buffer zones, duplicating the representative pore network to produce a set of generated pore networks, and stitching the set of generated pore networks according to the set of volumes and set of buffer zones to produce a digital plug.

Aspect 2: The method of aspect 1, further comprising: trimming the digital plug; defining inlet elements and outlet elements within the digital plug; and adjusting the digital plug to align with the porous media sample.

Aspect 3: The method of any one of aspects 1-2, wherein the porous drill cutting sample comprises a rock sample.

Aspect 4: An apparatus, comprising: a memory comprising executable instructions; and a processor configured to execute the executable instructions and cause the apparatus to perform a method in accordance with any one of Aspects 1-3.

Aspect 5: An apparatus, comprising means for performing a method in accordance with any one of Aspects 1-3.

Aspect 6: A non-transitory computer-readable medium comprising executable instructions that, when executed by a processor of an apparatus, cause the apparatus to perform a method in accordance with any one of Aspects 1-3.

Aspect 7: A computer program product embodied on a computer-readable storage medium comprising code for performing a method in accordance with any one of Aspects 1-3.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing, decomposing, and the like.

The methods disclosed herein comprise one or more operations or actions for achieving the methods. The method operations and/or actions may be interchanged with one another without departing from the scope of the claims. In other words, unless a specific order of operations or actions is specified, the order and/or use of specific operations and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in the Figures, those operations may have corresponding counterpart means-plus-function components with similar numbering.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A method for pore network generation by one or more central processing units (CPU), comprising:
obtaining a representative pore network having a set of representative pore elements corresponding to a porous media sample;
reading in geometries and relative locations of a set of volumes and a set of buffer zones of the digital plug;
randomizing selection of seed elements for the representative pore network;
inflating the seed elements to define the set of volumes and the set of buffer zones;
duplicating the representative pore network to produce a set of generated pore networks; and
stitching or blending the set of generated pore networks according to the set of volumes and set of buffer zones to produce a digital plug.

2. The method of claim 1, further comprising:
trimming the digital plug;
computing one or more statistics of the generated pore networks; and
adjusting the digital plug to align with the porous media sample.

3. The method of claim 1, wherein the porous media sample comprises a rock sample.

4. The method of claim 1, further comprising:
populating the buffer zones with the set of generated networks.

5. The method of claim 1, wherein obtaining a representative pore network comprises:
processing an input pore network;
computing a pore body volume density; and
computing and storing an adjacency list and a search radius of a plurality of pore bodies of the input pore network.

6. A non-transitory computer-readable medium for pore network generation comprising computer-executable instructions that, when executed by one or more processors, cause one or more processing units to:
obtain a representative pore network having a set of representative pore elements corresponding to a porous media sample;
discretize a domain of the digital plug and randomly determine a relative location of a component of the digital plug;
duplicate and stitch the representative pore network to fill the component of a digital plug;
define a set of buffer zones;
remove the representative pore elements from the set of buffer zones;
repopulate the set of buffer zones using the representative pore network to produce a set of generated pore networks; and
stitch the set of generated pore networks according to the set of volumes and set of buffer zones to produce the digital plug.

7. The non-transitory computer-readable medium of claim 6, further comprising:
trimming the digital plug;
defining inlet elements and outlet elements within the digital plug; and
adjusting the digital plug to align with the porous media sample.

8. The non-transitory computer-readable medium of claim 6, wherein the porous media sample comprises a rock sample.

9. The non-transitory computer-readable medium of claim 6, further comprising:
computing one or more statistics of the generated pore networks.

10. The non-transitory computer-readable medium of claim 6, wherein obtaining a representative pore network comprises:
processing the representative pore network;
computing a pore body volume density; and
computing and storing a search radius of a plurality of pore bodies of the representative pore network.

11. An apparatus for pore network generation comprising a memory and one or more processors, the one or more processors configured to cause the apparatus to:
obtain a representative pore network having a set of representative pore elements corresponding to a porous media sample;
read in geometries and relative locations of a set of volumes and a set of buffer zones of the digital plug;
randomize selection of a plurality of seed elements for the representative pore network;
inflate the plurality of seed elements to define a set of volumes and a set of buffer zones;
duplicate the representative pore network to produce a set of generated pore networks; and
stitch the set of generated pore networks according to the set of volumes and set of buffer zones to produce a digital plug.

12. The apparatus of claim 11, further comprising:
trimming the digital plug;
defining inlet elements and outlet elements within the digital plug; and
adjusting the digital plug to align with the porous media sample.

13. The apparatus of claim 11, wherein the porous media sample comprises a rock sample.

14. The apparatus of claim 11, wherein obtaining a representative pore network comprises:
processing an input pore network;
computing a pore body volume density; and
computing and storing an adjacency list and a search radius of a plurality of pore bodies of the input pore network.

15. The apparatus of claim 11, further comprising:
populating the buffer zones with the set of generated networks.
